(19) United States
(12) Patent Application Publication
(10) Pub. No.: US 2008/0308309 A1
(43) Pub. Date: Dec. 18, 2008

(54) Structure of packaging substrate having capacitor embedded therein and method for fabricating the same

(75) Inventors: Chung-Cheng Lien, Hsin-feng (TW); Chih-Kui Yang, Hsin-feng (TW)

Correspondence Address: BACON & THOMAS, PLLC, 625 SLATERS LANE, FOURTH FLOOR, ALEXANDRIA, VA, 22314-1176, US

(73) Assignee: Phoenix Precision Technology Corporation, Hsinchu (TW)

(21) Appl. No.: 11/808,962

(22) Filed: Jun. 14, 2007

(51) Int. Cl. H05K 1/16; H05K 3/10

(52) U.S. Cl. 174/260; 29/846

(57) ABSTRACT

A structure of a packaging substrate having capacitors embedded therein is disclosed. The structure comprises a core substrate, a dielectric layer, and an outer circuit layer. The core substrate comprises an inner circuit layer. The dielectric layer is disposed at both sides of the core substrate, having first conductive vias each connecting to the inner circuit layer through a piece of outer electrode plate, a piece of high dielectric material layer, a piece of inner electrode plate, and a piece of adhesive layer, in sequence. The outer circuit layer is disposed on the surface of each of the dielectric layers. Herein, the capacitor is composed of a piece of the outer electrode plate, the high dielectric material layer and the inner electrode plate. The invention further comprises a method for manufacturing the same. This can achieve low costs, avoid the formation of voids, and reduce parasitic capacitance.

### BACKGROUND OF THE INVENTION

1. Field of the Invention

The present invention relates to a structure of a packaging substrate having capacitors embedded therein and a method for fabricating the same, which can reduce the parasitic capacitance, avoid the formation of voids and poor uniformity of thickness resulted from the high dielectric material layer of prior art.

2. Description of Related Art

Currently, the relentless progress in semiconductor fabricating process and electronic functions of microelectronic devices has lead to a highly integrated development of semiconductor chips. Quantity of input/output terminals and density of wiring in package structures increase as semiconductor chips develop toward high integration. However, as the density of wiring in a package structure increases, the noise also increases. Generally, in order to obviate noise or compensate electricity, passive components, e.g. resistors, capacitors, and inductors, are installed in a semiconductor chip package structure to eliminate noise and to stabilize circuits to thereby meet the requirements of microelectronic devices.

In conventional methods, utilizing surface mount technology (SMT) integrates most passive components onto a surface of a packaging substrate, such that the flexibility of wiring layout on the surface is restricted, and the occupied space is unfavorable to shrinkage of package size.

In view of the aforementioned drawbacks, many studies relative to lamination methods have appeared in recent years. High dielectric coefficient material is laminated between two copper layers and then electrode plates and circuits are formed to fabricate capacitors. FIG. 1 shows a perspective view of a packaging substrate structure laminated with capacitors, wherein the process thereof comprises: providing an core substrate 10 having an inner circuit layer 11 having an inner electrode plate 111; forming a high dielectric material layer 12 on the inner circuit layer 11, and forming an outer circuit layer 13 on the high dielectric material layer 12, wherein the outer circuit layer 13 has a plurality of conductive pads 132 and an outer electrode plate 131, to thereby make a capacitor 17 through the outer electrode plate 131, the inner electrode plate 111, and a part of the high dielectric material layer 12 therebetween. The inner circuit layer 11 and the outer circuit layer 13 as well as the circuits on two sides of the substrate are electro-connected by a plated through holes (PTH) 14. In addition, a solder mask 15 was formed on the surfaces of the above structure, wherein the solder mask 15 has a plurality of openings 151 to expose the conductive pads 132 thereby accomplishing the packaging substrate.

However, the prior art forms a whole piece of high dielectric material layer within a packaging substrate, wherein the used part of the high dielectric material layer for a capacitor is merely the one between the inner electrode plate and the outer electrode plate, while the unused part of the high dielectric material layer electrically contacts with the circuits, such that the structure has several drawbacks: first, the unused part of the high dielectric material layer causes waste, unfavorable to reduce the cost; second, owing to the poor fluidity of the high dielectric material, voids and poor uniformity of thickness occur; third, the unused part of the high dielectric material layer electrically contacts the circuits, so that parasitic capacitance occurs to interfere with electrical qualities; finally, because the electrode plates and the circuits are laid together in a circuit layer, such that the flexibility of layouts of both the electrode plates and the circuits is compromised.

Therefore, it is desirable to provide a structure of a packaging substrate having capacitors embedded therein and a method for fabricating the same, to thereby reduce the parasitic capacitance, avoid the formation of voids and poor uniformity of thickness.

### SUMMARY OF THE INVENTION

In order to resolve the aforementioned disadvantages, the present invention provides a structure of a packaging substrate having capacitors embedded therein, comprising a core substrate, a dielectric layer, and an outer circuit layer. The core substrate has an inner circuit layer on each of two surfaces thereof. The dielectric layer is disposed on each of two sides of the core substrate, wherein a plurality of first conductive vias are disposed at least in one of the dielectric layers, each connecting to the inner circuit layer through a piece of outer electrode plate, a piece of high dielectric material layer, a piece of inner electrode plate, and a piece of adhesive layer in sequence. The outer circuit layer is disposed on the surface of each of the dielectric layers, wherein the first conductive vias electrically connects to the outer circuit layer of the same side. The capacitors are each composed of a piece of the outer electrode plate, a piece of the high dielectric material layer and a piece of the inner electrode plate.

The above structure further comprises in the dielectric layer at least one second conductive via electrically connecting the inner circuit layer and the outer circuit layer.

The above structure further comprises an outer plated through hole electrically connecting the outer circuit layers on the surfaces of the dielectric layers on two sides of the core substrate.

In the above structure the core substrate further comprises an inner plated through hole, so as to connect the inner circuit layers on two sides of the core substrate.

The packaging substrate structure having capacitors embedded therein can save production a lot of high dielectric material, avoid the formation of voids, and reduce the parasitic capacitance between the circuits.

The present invention also provides a method for manufacturing a structure of a packaging substrate having capacitors embedded therein, comprising the following steps: providing a metal plate first, wherein a plurality of high dielectric material layer pieces are formed on parts of the surface of the metal plate, and forming an inner electrode plate on the surface of the high dielectric material layer pieces each; subsequently, forming an adhesive layer on the surface of the inner electrode plate; then, connecting the metal plate through the adhesive layers to an core substrate having inner circuit layers formed on the two surfaces thereof; next, thinning the metal plate; removing the portion of the metal plate not connected to the high dielectric material layer pieces to form a plurality of outer electrode plates (i.e. the parts of the metal plate connecting to the high dielectric material layer pieces), and thereby accomplishing capacitors each consisting of a piece of outer electrode plate, a piece of high dielectric material layer and a piece of inner electrode plate; forming a dielectric layer on both surfaces of the core substrate by lamination, and forming in the dielectric layer a first via right on each of the outer electrode plates; and finally, forming by electroplating a first conductive via on the inside wall of each of the first vias as well as an outer circuit layer on the surfaces of the dielectric layer on each side of the core substrate at the same time.

In the present invention, in the dielectric layer at least one second via touching the inner circuit layer of the core substrate can further be formed after lamination of the dielectric layer. Then a second conductive via is formed in the second via at the same time when forming the first conductive vias and the outer circuit layers.

In addition, at least one through hole can be further formed in the dielectric layer before electroplating. The through hole extends through the core substrate and the dielectric layers on both sides of the core substrate. Then an outer plated through hole is formed in the through hole at the same time when forming the first conductive vias and the outer circuit layers.

In the present invention, an inner plated through hole can be further formed in the core substrate so as to connect the inner circuit layers on two sides of the core substrate.

The present invention can enhance the flexibility of layout of passive components and the circuit in the packaging substrate, as well as the usable surface area of the packaging substrate to meet the requirement of miniaturization.

In addition, the process of the present invention, fabricating a capacitor on the metal plate and then utilizing conductive vias or through holes for electro-connections, can save materials, avoid the formation of voids and poor uniformity of thickness, reduce the parasitic capacitance between the circuits, and simplify the process.

Other objects, advantages, and novel features of the invention will become more apparent from the following detailed description when taken in conjunction with the accompanying drawings.

### BRIEF DESCRIPTION OF THE DRAWINGS

FIG. 1 is a cross-section view of a structure of a packaging substrate having capacitors embedded therein fabricated by prior art; and

FIGS. 2A to 2H are cross-section views of a process of making a packaging substrate having capacitors embedded therein as a preferred embodiment of the present invention.

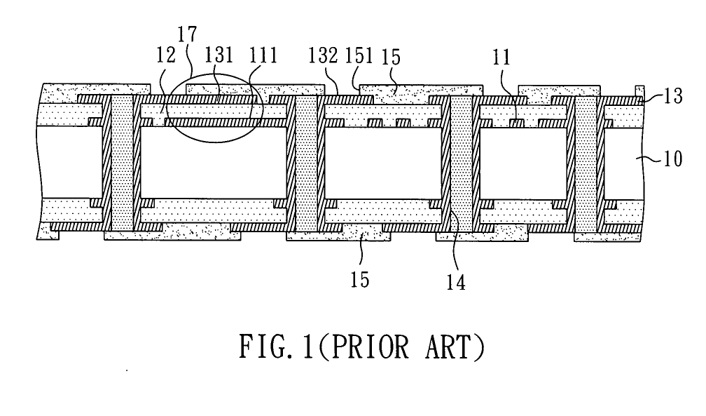

### DETAILED DESCRIPTION OF THE PREFERRED EMBODIMENT

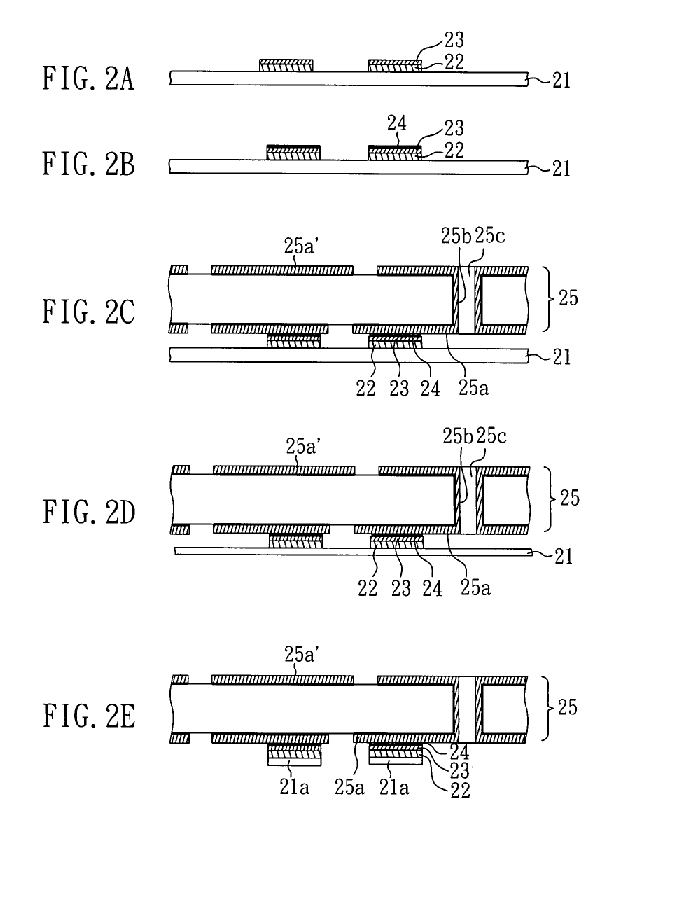

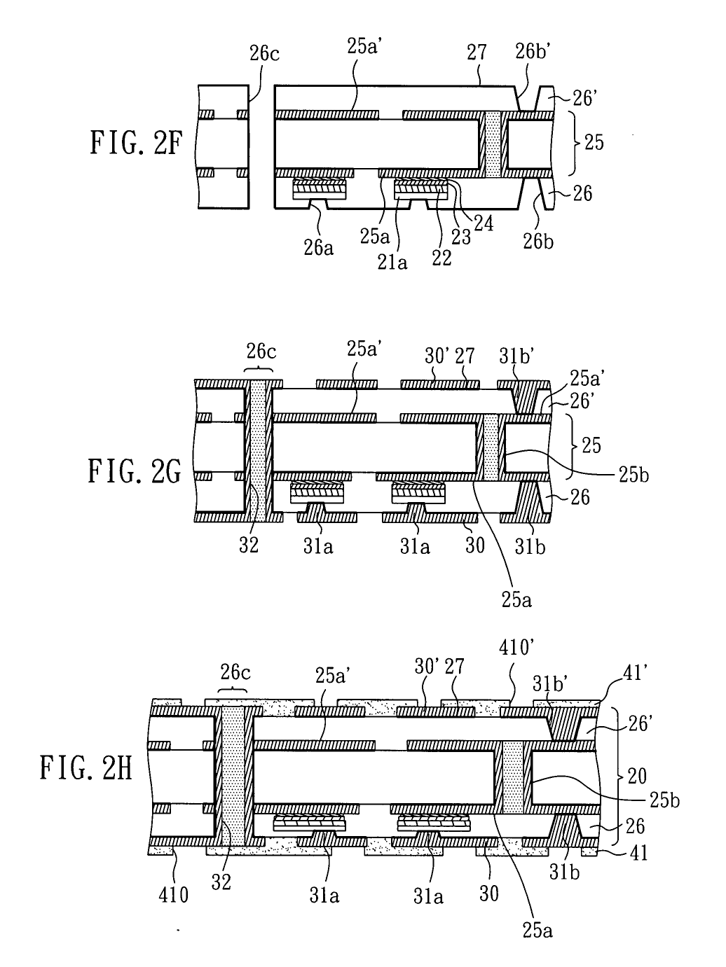

FIG. 2H is a cross-section view of a structure of the present invention about a packaging substrate having capacitors embedded therein. As shown in FIG. 2H, the semiconductor packaging substrate comprises an core substrate 25, two dielectric layers 26,26′, and outer circuit layer 30,30′. The core substrate 25 has inner circuit layers 25a,25a′ made of copper on two surfaces of the core substrate 25. The core substrate 25 can further comprise an inner plated through hole 25b so as to connect the inner circuit layers 25a,25a′. The dielectric layers 26,26′ are disposed on two sides of the core substrate 25, and the material of the dielectric layer 26, 26′ is selected from the group consisting of a non-photosensitive organic resin, a photosensitive organic resin (e.g. ABF (Ajinomoto Build-up Film), BCB (Benzocyclo-buthene), LCP (Liquid Crystal Polymer), PI (Poly-imide), PPE (Poly(phenylene ether)), PTFE (Poly (tetra-fluoroethylene)), FR4, FR5, BT (Bismaleimide Triazine), or Aramide), and a mixture of epoxy resin and fiber glass. In the present embodiment, the material of the dielectric layer 26 is ABF. The structure comprises a plurality of first conductive vias 31a and at least one second conductive via 31b or 31b′ disposed at least in one of the dielectric layers 26,26′. The first conductive vias 31a each connect to the inner circuit layer 25a through a piece of outer electrode plate 21a (also shown in FIG. 2F), a piece of high dielectric material layer 22, a piece of inner electrode plate 23 and a piece of adhesive layer 24 in sequence. The second conductive via 31b,31b′ electrically connects to the inner circuit layers 25a,25a′. The material of the outer electrode plate 21a is copper, aluminum, or a related alloy and the material of the high dielectric material layer 22 is ceramic. The material of the inner electrode plate 23 is copper or silver and the material of the adhesive layer 24 is selected from the group consisting of copper, tin, nickel, chromium, titanium, a copper/chromium alloy, and a tin/lead alloy. In the present embodiment, the material is tin. The capacitors are each composed of a piece of the outer electrode plate 21a, a piece of the high dielectric material layer 22 and a piece of the inner electrode plate 23.

Subsequently, outer circuit layers 30,30′ are disposed respectively on the surface of the dielectric layers 26,26′. The structure further comprises an outer plated through hole 32, which connects the outer circuit layers 30,30′ on the surfaces of the dielectric layer 26,26′. The material of the outer circuit layers 30,30′ and the outer plated through hole 32 is copper, tin, nickel, chromium, titanium, a copper/chromium alloy, or a tin/lead alloy. In the present embodiment, the material is copper.

The packaging substrate structure having capacitors embedded therein can save production a lot of high dielectric material, avoid the formation of voids, and reduce the parasitic capacitance between the circuits.

The present invention also provides a manufacturing method for a structure of a packaging substrate having capacitors embedded therein, as shown in FIGS. 2A to 2H.

As shown in FIG. 2A, a metal plate 21 is provided, first. The material of the metal plate 21 can be copper. A plurality of high dielectric material layer pieces 22 are formed on parts of the surface of the metal plate 21 by coating or printing a paste of polymeric material, ceramic material, polymeric material filled with ceramic powder, or a mixture of similarity thereof, then an inner electrode plate 23 is formed on the surface of the high dielectric material layer pieces 22 each by coating or printing copper paste or silver paste, and then the above structure undergoes high-temperature sintering, so that the dielectric coefficient of the high dielectric material layer 22 is 40˜4000.

Subsequently, as shown in FIG. 2B, an adhesive layer 24 is formed on the surface of the inner electrode plate 23 by screen printing tin paste. Through reflowing, as shown in FIG. 2C, the adhesive layer 24 connects the above structure with the inner circuit layer 25a at one side of the core substrate 25.

Then, as shown in FIG. 2D, the metal plate 21 is thinned by etching. As shown in FIG. 2E, the portion of the metal plate 21 not connecting to the high dielectric material layer 22 is removed by etching and the parts of the metal plate connecting to the high dielectric material layer pieces 22 remain and serve as outer electrode plates 21a, and thereby accomplishing capacitors each consisting of a piece of outer electrode plate 21a, a piece of a high dielectric material layer 22 and a piece of inner electrode plate 23.

As shown in FIG. 2F, dielectric layers 26, 26′ or resin coated copper (not shown) are disposed on both sides of the core substrate 25 by lamination. First vias 26a and second vias 26b, 26b′ are formed in the dielectric layer by laser ablation. Through hole 26c penetrating the dielectric layers 26,26′ and the core substrate 25 are formed by machine-drilling. Then, a seed layer 27 is formed on the surface of the structure (including the inside walls of the first vias 26a, the second vias 26b, 26b′, and the through hole 26c) by electroless plating. The seed layer 27 serves as a conductive medium needed for the following electroplating process. The material of the seed layer 27 can be copper.

Then, as shown in FIG. 2G, circuit layers 30, 30′ are respectively formed on the surfaces of the dielectric layers 26,26′ by electroplating through the seed layer 27. The electroplating process is well known in the art, thus not to be described further there.

Furthermore, as shown in FIG. 2H, a solder mask 41,41′ are coated on the surfaces of the above structure, wherein the solder mask 41,41′ has a plurality of openings 410,410′ to expose parts of the circuit layer 30,30′ as bond pads, so as to suffice for solder bumps and solder balls (not shown). Thereby, the present invention provides a structure of a packaging substrate 20 having capacitors embedded therein, which can electrically connect to a chip through the solder bumps, and electrically connect to another electronic device through the solder balls (not shown).

The present invention can enhance the flexibility of layout of passive components and the circuit in the packaging substrate, as well as the usable surface area of the packaging substrate to meet the requirement of miniaturization.

In addition, the process of the present invention, fabricating a capacitor on the metal plate and then utilizing conductive vias or through holes for electro-connections, can save materials, avoid the formation of voids and poor uniformity of thickness, reduce the parasitic capacitance between the circuits, and simplify the process.

Although the present invention has been explained in relation to its preferred embodiment, it is to be understood that many other possible modifications and variations can be made without departing from the spirit and scope of the invention as hereinafter claimed.

What is claimed is:

1. A structure of a packaging substrate having capacitors embedded therein, comprising:
a core substrate having an inner circuit layer on each of two surfaces thereof;
a dielectric layer disposed on each of two sides of the core substrate, wherein a plurality of first conductive vias are disposed at least in one of the dielectric layers, each connecting to the inner circuit layer through a piece of outer electrode plate, a piece of high dielectric material layer, a piece of inner electrode plate, and a piece of adhesive layer in sequence to make a capacitor; and
an outer circuit layer, disposed on the surface of each of the dielectric layers, wherein the first conductive vias electrically connects to the outer circuit layer of the same side.

2. The structure as claimed in claim 1, further comprising at least one second conductive via in the dielectric layers electrically connecting the inner circuit layer and the outer circuit layer.

3. The structure as claimed in claim 1, further comprising an outer plated through hole connecting the outer circuit layers on the surfaces of the dielectric layers on two sides of the core substrate.

4. The structure as claimed in claim 1, wherein the core substrate further comprises an inner plated through hole, so as to connect the inner circuit layers on two sides of the core substrate.

5. The structure as claimed in claim 1, wherein the material of the outer electrode plate is copper, aluminum, or a related alloy.

6. The structure as claimed in claim 1, wherein the material of the high dielectric material layer is polymeric material, ceramic material, polymeric material filled with ceramic powder, or a mixture of similarity thereof.

7. The structure as claimed in claim 1, wherein the dielectric coefficient of the high dielectric material layer is 40˜4000.

8. The structure as claimed in claim 1, wherein the material of the inner electrode is copper paste or silver paste.

9. The structure as claimed in claim 1, wherein the material of the adhesive layer is selected from the group consisting of copper, tin, nickel, chromium, titanium, a copper/chromium alloy, and a tin/lead alloy.

10. A method for manufacturing a structure of a packaging substrate having capacitors embedded therein, comprising the following steps:
providing a metal plate, wherein a plurality of high dielectric material layer pieces are formed on parts of the surface of the metal plate and an inner electrode plate is formed on surface of the high dielectric material layer pieces each;
forming an adhesive layer on the surface of the inner electrode plate;
connecting the metal plate through the adhesive layers to a core substrate having inner circuit layers formed on the two surfaces thereof;
thinning the metal plate;
removing the portion of the metal plate not connected to the high dielectric material layer pieces to form a plurality of outer electrode plates;
forming a dielectric layer on both sides of the core substrate by lamination, and forming in the dielectric layer a first via right on each of the outer electrode plates; and
forming by electroplating a first conductive via on the inside wall of each of the first vias as well as an outer circuit layer on the surface of the dielectric layer on each side of the core substrate at the same time.

11. The method as claimed in claim 10, wherein in the dielectric layer at least one second via touching the inner circuit layer of the core substrate is further formed after lamination of the dielectric layer, and a second conductive via is then formed in the second via at the same time when forming the first conductive vias and the outer circuit layers.

12. The method as claimed in claim 10, wherein at least one through hole extends through the core substrate and the dielectric layers on both sides of the core substrate is further formed in the dielectric layer before electroplating, and then an outer plated through hole is formed in the through hole at the same time when forming the first conductive vias and the outer circuit layers.

13. The method as claimed in claim 10, wherein the core substrate further comprises an inner plated through hole, so as to connect the inner circuit layers on two sides of the core substrate.

14. The method as claimed in claim 10, wherein the high dielectric material layer and the inner electrode plate are formed by sputtering, coating, or printing.

15. The method as claimed in claim 10, wherein the adhesive layer is formed by screen printing.
